(19) United States
(12) Patent Application Publication
(10) Pub. No.: US 2021/0324530 A1
(43) Pub. Date: Oct. 21, 2021

(54) MASK, MASK ASSEMBLY, AND METHOD FOR MANUFACTURING THE MASK

(71) Applicant: Kunshan Go-Visionox Opto-Electronics Co., Ltd., Kunshan (CN)

(72) Inventors: Mingxing LIU, Kunshan (CN); Xuliang WANG, Kunshan (CN); Feng GAO, Kunshan (CN); Xuan ZHANG, Kunshan (CN); Shuaiyan GAN, Kunshan (CN)

(21) Appl. No.: 16/339,001

(22) PCT Filed: Nov. 1, 2018
(86) PCT No.: PCT/CN2018/113501

§ 371 Date: Apr. 3, 2019

(30) Foreign Application Priority Data
May 14, 2018 (CN) 201810457657.9

(51) Int. Cl. C25D 1/10; C23C 14/04

(52) U.S. Cl. CPC C25D 1/10; H01L 51/56; C23C 14/042

(57) ABSTRACT

The present disclosure relates to masks, mask assemblies, and methods for manufacturing masks. The mask is configured to be tensioned and soldered on a support frame. The mask is an electroformed mask. The mask includes an evaporation area, a non-evaporation area, and a soldering area used to be soldered to the support frame. At least the soldering area is doped with magnetic metal ions, thereby improving soldering performance of the soldering area.

### FIELD

The present disclosure relates to the field of display panel manufacturing technologies, and more particularly relates to masks, mask assemblies, and methods for manufacturing masks.

### BACKGROUND

Currently, organic light-emitting diode (OLED) adopts vacuum evaporation technology to manufacture an organic light-emitting layer. During a manufacturing process of a device, organic materials are deposited on a substrate located above an evaporation source by high-temperature evaporation. In order to evaporate the organic materials to a specific location as designed, a mask is required. A pre-designed effective opening area is left on the mask, and the organic materials can be deposited onto a back plate through the effective opening area to form a predetermined pattern.

A mask is generally manufactured by an etching process or an electroforming process. In actual production, the inventors have found that masks manufactured by electroforming processes have poor soldering performance and are not easy to be tensioned and soldered to the support frame. The soldering result between a mask and a support frame is poor.

### SUMMARY

Accordingly, a mask is provided to solve the problem of poor soldering performance of an electroformed mask, and to ensure the soldering effect between a mask and a support frame.

In order to achieve the above object, the present disclosure provides masks.

A mask is adapted for being tensioned and soldered on a support frame, and the mask is an electroformed mask. The mask includes an evaporation area, a non-evaporation area, and a soldering area soldered to the support frame. At least the soldering area is doped with magnetic metal ions to improve soldering performance of the soldering area.

In the aforementioned mask, at least the soldering area is doped with magnetic metal ions, so as to improve the soldering performance of the soldering area. Since the magnetic metal ions have good soldering performance, after the magnetic metal ions are doped into the soldering area of the mask, the content of ions with better soldering performance in the soldering area is increased, thereby improving the soldering performance of the soldering area and ensuring the soldering effect between the mask and the support frame.

In one of the embodiments, an entire area of the mask is doped with the magnetic metal ions.

In one of the embodiments, the evaporation area is doped with the magnetic metal ions to improve magnetic attraction performance of the evaporation area.

In one of the embodiments, the magnetic metal ions are iron-based ions and/or nickel-based ions.

In one of the embodiments, the non-evaporation area is doped with non-magnetic ions to reduce magnetic attraction performance of the non-evaporation area.

In one of the embodiments, a mass ratio of the non-magnetic ions in all ions of the mask is less than 0.5%.

In one of the embodiments, the non-magnetic ions are at least one of titanium ions, manganese ions, and carbon ions.

A mask assembly includes a support frame and at least one of the aforementioned masks. The mask is tensioned and soldered on the support frame.

The present disclosure further provides a method for manufacturing a mask, which includes:

providing a mask, and the mask includes an evaporation area, a non-evaporation area, and a soldering area soldered to a support frame; and

doping magnetic metal ions at least in the soldering area of the mask to improve soldering performance of the soldering area.

In one of the embodiments, the doping magnetic metal ions at least in the soldering area of the mask includes: implanting the magnetic metal ions in at least the soldering area of the mask by ion implantation.

In one of the embodiments, the doping magnetic metal ions at least in the soldering area of the mask includes: implanting the magnetic metal ions in the soldering area and the evaporation area by ion implantation.

In one of the embodiments, the magnetic metal ions are iron-based ions and/or nickel-based ions.

In one of the embodiments, the method for manufacturing the mask further includes: implanting non-magnetic ions in the non-evaporation area by ion implantation.

In one of the embodiments, the non-magnetic ions are at least one of titanium ions, manganese ions, and carbon ions

In one of the embodiments, the doping magnetic metal ions at least in the soldering area of the mask includes: implanting the magnetic metal ions in an entire area of the mask by ion implantation.

### BRIEF DESCRIPTION OF THE DRAWINGS

FIG. 1 is a schematic view of a mask assembly according to an embodiment of the present disclosure;

FIG. 2 is a schematic view of a mask according to an embodiment of the present disclosure; and

FIG. 3 is a flowchart of a method for manufacturing a mask according to an embodiment of the present disclosure.

### DETAILED DESCRIPTION OF THE INVENTION

In order to facilitate the understanding of the present disclosure, embodiments of the disclosure are described more fully hereinafter with reference to the accompanying drawings. The various embodiments of the disclosure may, however, be embodied in many different forms and should not be construed as limited to the embodiments set forth herein. Rather, these embodiments are provided so that this disclosure will be thorough and complete, and will fully convey the scope of the disclosure to those skilled in the art.

It will be understood that when an element is referred to as being “fixed” to another element, it can be directly on the other element or intervening elements may be present. when an element is referred to as being “connected” or “coupled” to another element, it can be directly connected or coupled to the other element or intervening elements may be present.

Unless otherwise defined, all terms (including technical and scientific terms) used herein have the same meaning as commonly understood by one of ordinary skill in the art to which this disclosure belongs. The terms used herein in the specification of the present disclosure are for the purpose of describing specific embodiments only and are not intended to limit the present disclosure. The terms “and/or” used herein includes any and all combinations of one or more associated listed items.

As described in the background art, the problem of poor soldering performance occurs when using an electroforming mask in the prior art. The inventors have found that the fundamental reason for this problem is that when using the mask manufactured by an electroforming process, since the electroforming solution has strong corrosion resistance, the soldering performance of the formed mask will be weakened. Specifically, the soldering belongs to a process of destroying the structure of the metal itself, and the presence of corrosion-resistant ions in the electroforming solution causes the metal ions in the finally formed mask to be less likely to change, which in turn results in poor soldering performance.

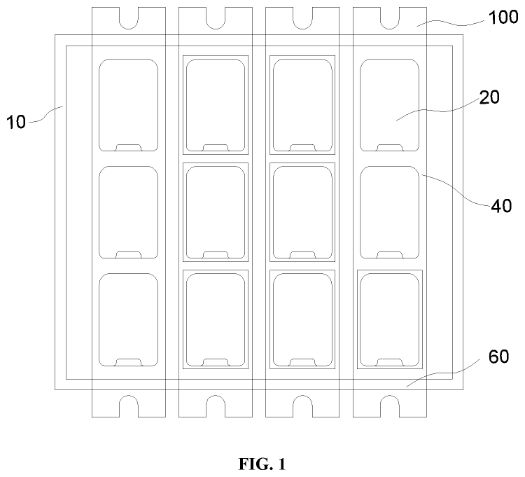

Referring to FIGS. 1 to 2, accordingly, the present disclosure discloses a mask 100, which is tensioned on a support frame 10 and is used to evaporate pixel units of a display panel, and the like. The mask 100 is an electroformed mask, which is manufactured by an electroforming process, and has a thin thickness and a good evaporation effect.

The mask 100 includes an evaporation area 20, a non-evaporation area 40, and a soldering area 60 used to be soldered to a support frame 10. When the mask 100 is tensioned on the support frame 10, the evaporation area 20 and the non-evaporation area 40 are located within a hollow area of the support frame 10, and the soldering area 60 is used to be soldered to the support frame 10. At least the soldering area 60 is doped with auxiliary ions. Since the soldering performance of the auxiliary ions is superior to the soldering performance of the corrosion-resistant ions in the electroforming solution used for manufacturing the mask 100, the soldering performance of the soldering area 60 is improved. Since the auxiliary ions have good soldering performance, after the auxiliary ions are doped into the soldering area 60, the content of ions with better soldering performance in the soldering area 60 is increased, thereby improving the soldering performance of the soldering area 60 and ensuring the soldering effect between the mask 100 and the support frame 10.

Preferably, the auxiliary ions are magnetic metal ions. The magnetic metal ions improve the overall soldering performance of the mask 100, and can be magnetically attracted in the magnetic field, thereby further improving the attraction performance of the mask 100 and preventing the mask 100 from drooping during the evaporation process, and further improving the evaporation effect.

In one of the embodiments, an entire area of the mask 100 is doped with the magnetic metal ions, thereby further improving the overall soldering performance of the mask 100.

In one of the embodiments, the evaporation area 20 is doped with the auxiliary ions, specifically, the auxiliary ions doped in the evaporation area 20 are the magnetic metal ions, thereby improving the attraction performance of the evaporation area. Since the magnetic metal ions themselves are subjected to a strong magnetic force in the magnetic field, after the magnetic metal ions are implanted into the evaporation area 20, the attraction force of the evaporation area 20 in the magnetic field is enhanced, thus enhancing the attraction performance of the magnetic field on the evaporation area 20.

When the mask 100 is stretched and tensioned on the support frame 10, since the evaporation area 20 is provided with a plurality of evaporation openings, the evaporation area 20 has a low overall strength and is easily deformed and drooped when subjected to gravity. In the present embodiment, by increasing the magnetic metal ions in the evaporation area 20, the attraction performance of the evaporation area 20 can be improved, and the aforementioned problem of deformation and drooping of the evaporation area 20 can be improved, so that the evaporation area 20 having a large amount of drooping is subjected to a larger attraction force, and the difference in the amount of drooping between the evaporation area 20 and the surrounding area thereof is reduced, thereby further reducing the phenomenon that the edge of the evaporation area 20 is wrinkled due to the drooping of the evaporation area 20.

In general, the corrosion-resistant ions in the mask are mostly cobalt ions or titanium ions. Therefore, the aforementioned magnetic metal ions can be iron-based ions and/or nickel-based ions, that is, the magnetic metal ions used for doping may be iron-based ions, nickel-based ions, or a mixture of iron-based ions and nickel-based ions.

In one embodiment, the non-evaporation area 40 is doped with non-magnetic ions, thereby reducing the attraction performance of the non-evaporation area 40. The non-magnetic ions themselves are not subjected to the magnetic attraction force in the magnetic field, after the non-magnetic ions are implanted into the non-evaporation area 40, the attraction performance of the magnetic field on the non-evaporation area 40 is weakened due to an increase in the content of the non-magnetic ions in the non-evaporation area 40. Optionally, the non-magnetic ions are at least one selected from the group consisting of titanium ions, manganese ions, and carbon ions. In other words, the non-magnetic ions may be any one of the above three ions, or a mixture of at least two of the above three ions.

When the mask 100 is stretched and tensioned on the support frame 10, since the evaporation area 20 is provided with a plurality of evaporation openings, the evaporation area 20 has a lower strength with respect to the non-evaporation area 40 at its outer periphery, and the amount of drooping of the evaporation area 20 is greater than that of the non-evaporation area 40 under gravity. The transitional edge between the two areas is easily wrinkled due to the large difference in the amount of drooping.

In order to improve the aforementioned phenomenon, in the present embodiment, on the basis of implanting the magnetic metal ions into the evaporation area 20 having a large amount of drooping, the non-magnetic ions are also implanted into the non-magnetic area 40, thereby weakening the attraction capacity of an area having a small amount of drooping. When the evaporation area 20 and the non-evaporation area 40 are located in the same magnetic field, the evaporation area 20 is subjected to a strong attraction force to avoid excessive amount of drooping, the non-evaporation area 40 is subjected to a weaker attraction force to prevent the amount of drooping from being too small, and finally the amount of drooping of the two areas of the evaporation area 20 and the non-evaporation area 40 is close to each other, thus the evaporation area 20 and the non-evaporation area 40 are substantially in the same plane, thereby reducing the wrinkles produced at the transitional edge of the two areas.

Preferably, a mass ratio of the non-magnetic ions in all ions of the mask 100 is less than 0.5%. By doping with a small amount of the non-magnetic ions, the excessive amount of the non-magnetic ions can be prevented from adversely affecting the metal ions in the mask 100. Herein, the all ions of the mask 100 refer to various ions constituting the entirety of the mask 100.

In one embodiment, the evaporation area 20 matches with a display area of an irregular-shaped display screen, and the evaporation area 20 is an irregular-shaped area. After the mask 100 is stretched and tensioned, the irregular-shaped evaporation area 20 droops due to the weight, and the transitional edge of the irregular-shaped evaporation area 20 and the surrounding non-evaporation area 40 is easily wrinkled due to the difference in the amount of drooping. In addition, the irregular-shaped edge tends to intensify the wrinkles due to uneven force during the drooping process.

With respect to the irregular-shaped evaporation area 20, the mask 100 of the aforementioned embodiment of the present disclosure is used to dope the magnetic metal ions and the non-magnetic ions by partitioning (specifically, the magnetic metal ions are implanted into the evaporation area 20 having a large amount of drooping to enhance the attraction force, and the non-magnetic ions are implanted into the non-evaporation area 40 having a small amount of drooping to weaken the attraction force), so that the evaporation area 20 and the non-evaporation area 40 are maintained at a close height under gravity and magnetic force, thus effectively preventing the transitional edge of the two areas from being wrinkled due to the large difference in the amount of drooping.

An embodiment of the present disclosure further provides a mask assembly. Referring to FIG. 1, the mask assembly includes the aforementioned mask 100 and the support frame 10. The mask 100 is tensioned and soldered on the support frame 10, and can be used to evaporate pixel units of a display panel, and the like.

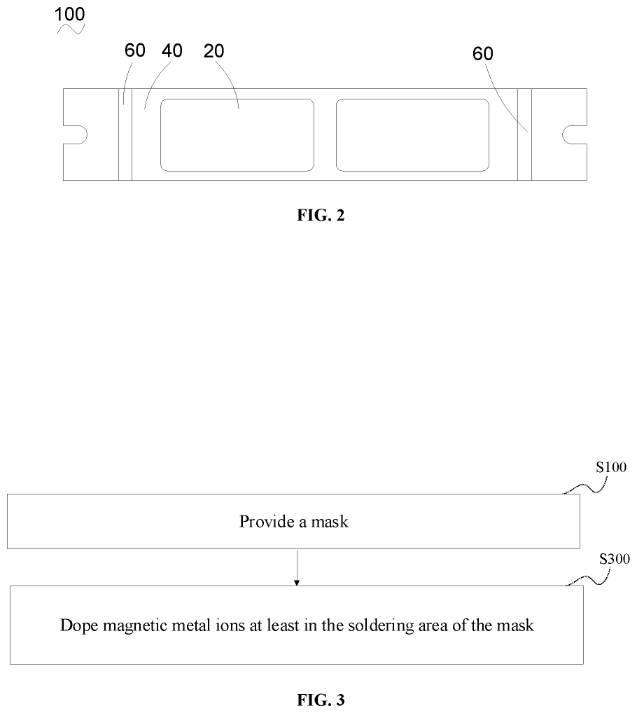

Referring to FIG. 3, an embodiment of the present disclosure further provides a method for manufacturing the mask, which specifically includes the following steps:

In step S100, a mask 100 is provided, which includes an evaporation area 20, a non-evaporation area 40, and a soldering area 60 used to be soldered to a support frame 10.

In step S300, magnetic metal ions are doped at least in the soldering area 60 of the mask 100. Since the soldering performance of the magnetic metal ions is superior to the soldering performance of the corrosion-resistant ions in the electroforming solution used for manufacturing the mask 100, the soldering performance of the soldering area 60 is improved.

In the aforementioned method for manufacturing the mask, the mask 100 distributed with a plurality of evaporation openings is electroformed, and a thickness of the mask 100 is thin, so that the evaporation effect is good. After the mask is obtained by electroforming, the magnetic metal ions are implanted into the soldering area 60 of the mask 100. The magnetic metal ions themselves have strong soldering performance, and the magnetic metal ions such as iron having strong soldering performance are implanted into the soldering area 60 by ion implantation technology, and the content of the magnetic ions in the soldering area 60 is increased, so that the soldering performance of the soldering area 60 can be enhanced, and the soldering effect between the mask 100 and the support frame 10 can be ensured.

In one embodiment, the step S300 of doping the magnetic metal ions at least in the soldering area 60 of the mask 100 includes: implanting the magnetic metal ions in at least the soldering area 60 of the mask by using an ion implantation process to enhance the soldering performance of the soldering area 60 and ensure the soldering effect between the mask 100 and the support frame 10.

In another embodiment, the step S300 of doping the magnetic metal ions at least in the soldering area 60 of the mask 100 includes: implanting the magnetic metal ions in the soldering area 60 and the evaporation area 20 by using the ion implantation process, thereby improving the soldering performance of the soldering area 60. In addition, the magnetic metal ions can be iron-based ions and/or nickel-based ions. Since the magnetic metal ions themselves are subjected to a strong magnetic force in the magnetic field, after the magnetic metal ions are implanted into the evaporation area 20, the magnetic attraction force of the evaporation area 20 in the magnetic field is enhanced, so that the attraction performance of the magnetic field on the evaporation area 20 can be enhanced.

After the mask 100 is stretched and tensioned on the support frame 10, since the evaporation area 20 is provided with a plurality of evaporation openings, the evaporation area 20 has a low overall strength and is easily deformed and drooped when subjected to gravity. In the present embodiment, by increasing the attraction performance of the evaporation area 20, the evaporation area 20 having a large amount of drooping is subjected to a larger attraction force, so that the drooping phenomenon of the evaporation area is effectively improved, and the difference in the amount of drooping between the evaporation area 20 and the surrounding area thereof is reduced, thereby further reducing the phenomenon that the edge of the evaporation area 20 is wrinkled due to the drooping of the evaporation area 20.

In another embodiment, the step S300 of doping the magnetic metal ions at least in the soldering area 60 of the mask 100 includes: implanting the magnetic metal ions in an entire area of the mask 100 by using the ion implantation process to enhance the overall soldering performance of the mask 100 and ensure the soldering effect between the mask 100 and the support frame 10. In addition, the doped magnetic metal ions can also improve the magnetic attraction performance of the mask 100, and prevent the mask 100 from drooping during the evaporation process.

In one embodiment, the method for manufacturing the mask further includes the following steps:

In step S500, non-magnetic ions are implanted into the non-evaporation area by using the ion implantation process. For example, the non-magnetic ions are at least one selected from the group consisting of titanium ions, manganese ions, and carbon ions. The non-magnetic ions themselves are not subjected to the magnetic attraction force in the magnetic field, after the non-magnetic ions are implanted into the non-evaporation area 40, the attraction performance of the magnetic field on the non-evaporation area 40 is weakened due to an increase in the content of the non-magnetic ions in the non-evaporation area 40. Optionally, the non-magnetic ions are at least one selected from the group consisting of titanium ions, manganese ions, and carbon ions. In other words, the non-magnetic ions may be any one of the above three ions, or a mixture of at least two of the above three ions.

When the mask 100 is stretched and tensioned on the support frame 10, since the evaporation area 20 is provided with a plurality of evaporation openings, the evaporation area 20 has a lower strength with respect to the non-evaporation area 40 at its outer periphery, and the amount of drooping of the evaporation area 20 is greater than that of the non-evaporation area 40 under gravity. The transitional edge between the two areas is easily wrinkled due to the large difference in the amount of drooping. In order to improve the aforementioned phenomenon, in the present embodiment, on the basis of implanting the magnetic metal ions into the evaporation area 20 having a large amount of drooping, the non-magnetic ions are also implanted into the non-magnetic area 40, thereby weakening the attraction capacity of an area having a small amount of drooping. When the evaporation area 20 and the non-evaporation area 40 are located in the same magnetic field, the evaporation area 20 is subjected to a strong attraction force to avoid excessive amount of drooping, the non-evaporation area 40 is subjected to a weaker attraction force to prevent the amount of drooping from being too small, and finally the amount of drooping of the two areas of the evaporation area 20 and the non-evaporation area 40 is close to each other, thus the evaporation area 20 and the non-evaporation area 40 are substantially in the same plane, thereby reducing the wrinkles produced at the transitional edge of the two areas.

The technical features of the above-described embodiments may be combined in any combination. For the sake of brevity of description, all possible combinations of the various technical features in the above embodiments are not described. However, as long as there is no contradiction in the combination of these technical features, it should be considered as the scope of the present specification.

The foregoing embodiments are merely illustrative of several embodiments of the present disclosure, and the description thereof is more specific and detailed, but is not to be construed as limiting the scope of the disclosure. It should be noted that any variation or replacement readily figured out by a person skilled in the art without departing from the concept of the present disclosure shall all fall within the protection scope of the present disclosure. Therefore, the protection scope of the present disclosure shall be subject to the protection scope of the appended claims.

1. A mask, adapted for being tensioned and soldered on a support frame, the mask being an electroformed mask, wherein the mask comprises an evaporation area, a non-evaporation area, and a soldering area soldered to the support frame, wherein at least the soldering area is doped with magnetic metal ions to improve soldering performance of the soldering area.

2. The mask according to claim 1, wherein an entire area of the mask is doped with the magnetic metal ions.

3. The mask according to claim 1, wherein the evaporation area is doped with the magnetic metal ions to improve magnetic attraction performance of the evaporation area.

4. The mask according to claim 2, wherein the magnetic metal ions comprise at least one of iron-based ions and nickel-based ions.

5. The mask according to claim 1, wherein the non-evaporation area is doped with non-magnetic ions to reduce magnetic attraction performance of the non-evaporation area.

6. The mask according to claim 5, wherein a mass ratio of the non-magnetic ions to the non-magnetic ions and the magnetic metal ions of the mask is less than 0.5%.

7. The mask according to claim 5, wherein the non-magnetic ions are at least one of titanium ions, manganese ions, and carbon ions.

8. A mask assembly, comprising a support frame and a mask of claim 1, wherein the mask is tensioned and soldered on the support frame.

9. A method for manufacturing a mask, the method comprising:
providing a mask, wherein the mask comprises an evaporation area, a non-evaporation area, and a soldering area soldered to a support frame; and
doping magnetic metal ions at least in the soldering area of the mask to improve soldering performance of the soldering area.

10. The method for manufacturing the mask according to claim 9, wherein the doping magnetic metal ions at least in the soldering area of the mask comprises: implanting the magnetic metal ions in at least the soldering area of the mask by ion implantation.

11. The method for manufacturing the mask according to claim 9, wherein the doping magnetic metal ions at least in the soldering area of the mask comprises: implanting the magnetic metal ions in the soldering area and the evaporation area by ion implantation.

12. The method for manufacturing the mask according to claim 9, wherein the magnetic metal ions comprise at least one of iron-based ions and nickel-based ions.

13. The method for manufacturing the mask according to claim 9, further comprising: implanting non-magnetic ions in the non-evaporation area by ion implantation.

14. The method for manufacturing the mask according to 13, wherein the non-magnetic ions are at least one of titanium ions, manganese ions, and carbon ions.

15. The method for manufacturing the mask according to claim 9, wherein the doping magnetic metal ions at least in the soldering area of the mask comprises: implanting the magnetic metal ions in an entire area of the mask by ion implantation.

16. The method for manufacturing the mask according to claim 13, wherein a mass ratio of the non-magnetic ions to the non-magnetic ions and the magnetic metal ions of the mask is less than 0.5%.

17. The method for manufacturing the mask according to claim 9, wherein the mask is provided with a plurality of evaporation openings in the evaporation area.

18. The mask according to claim 1, wherein the mask is provided with a plurality of evaporation openings in the evaporation area.

19. The mask assembly according to claim 8, wherein an entire area of the mask is doped with the magnetic metal ions.
